(19) United States
(12) Patent Application Publication
(10) Pub. No.: US 2013/0088233 A1
(43) Pub. Date: Apr. 11, 2013

(54) Shield for Electronic Circuit

(71) Applicants: Sebastian Martius, Forchheim (DE); Benjamin Sewiolo, Hoechstadt (DE)

(72) Inventors: Sebastian Martius, Forchheim (DE); Benjamin Sewiolo, Hoechstadt (DE)

(21) Appl. No.: 13/646,484

(22) Filed: Oct. 5, 2012

(30) Foreign Application Priority Data
Oct. 6, 2011 (DE) DE 102011084071.0

(51) Int. Cl. G01R 33/42

(52) U.S. Cl. 324/322

(57) ABSTRACT

A metal structure includes a plurality of non-contiguous subsections on a substrate. The subsections are at least partially capacitively connected to one another. This is achieved by the subsections having overlaps on both sides of the substrate and/or by the subsections being connected to one another by capacitors. The capacitive coupling produced constitutes a short circuit for high frequencies and an open circuit for low frequencies. This results in the frequency-selective surface.

This application claims the benefit of DE 10 2011 084 071.0, filed on Oct. 6, 2011, which is hereby incorporated by reference.

### BACKGROUND

The present embodiments relate to a shield for an electronic circuit.

Magnetic resonance tomography (MRT or MR; magnetic resonance imaging (MRI)) is an imaging method that is employed in the medical diagnostics field for visualizing the structure and function of the tissues and organs in the body. MRT is based on the principles of nuclear spin magnetic resonance and is therefore also referred to as nuclear spin tomography. General details may be found, for example, at http://de.wikipedia.org/wiki/Magnetresonanztomographie or http://en.wikipedia.org/wiki/Magnetic_resonance_imaging.

With MRT, sectional images (e.g., slices) of the human (or animal) body may be generated. The sectional images permit an assessment of the organs and many pathological organ changes. Magnetic resonance tomography is based on strong magnetic fields and alternating electromagnetic fields in the radio frequency domain, using which certain atomic nuclei (e.g., the hydrogen nuclei/protons) in the body are excited into resonance and induce electrical signals in the receiver circuit. No harmful x-ray or other ionizing radiation is generated or used in the device. Different relaxation times of different types of tissue are a basis for the image contrast. The different concentration of hydrogen atoms in different tissues (e.g., muscle, bone) is also a basis for the image contrast.

In addition to the basic static magnetic field, switched gradient magnetic fields in the kHz range and the MR frequency in the upper MHz range (e.g., 60-500 MHz) are used in MRT. Advances in integration increasingly require electronics modules to be arranged directly at the highly sensitive receive coils (e.g., local coils). In such an arrangement, the electronics modules may interfere with the reception of the MR signals. The electronic components are thus to be shielded in an appropriate manner.

One problem that exists in this situation is that the shielding for the electronics modules is to be as high as possible in the MR frequency range and yet be as transparent as possible to the gradient frequency (e.g., the shield may possess low-pass characteristics).

It is known that electronic assemblies may be shielded with the aid of continuous metal boxes or metal covers. However, it is disadvantageous in this case that eddy currents may be induced on shielding elements of this type due to the continuous metal surfaces. The currents lead to image-degrading interference effects during magnetic resonance tomography. In the prior art, the electronics modules causing the interference are disposed at a safe distance and connected to the receive antennas by cables. This results in an increased level of cabling complexity, which is detrimental to safety and allows the costs of such a solution to rise.

### SUMMARY AND DESCRIPTION

The present embodiments may obviate one or more of the drawbacks or limitations in the related art. For example, efficient, cost-effective and safe shielding of interfering electronic assemblies, so that the interfering electronic assemblies may be disposed in immediate proximity to the receive antenna, is provided.

A shield for an electronic circuit includes a substrate and a metal structure that is arranged on at least one side of the substrate. The metal structure has a plurality of non-contiguous subsections. The subsections of the metal structure are at least partially capacitively connected to one another.

The capacitive coupling produced includes a short circuit for high frequencies and an open circuit for low frequencies. This results in a frequency-selective surface that exhibits low-pass characteristics.

Using the substrate and the structuring of the metal surface, a frequency-selective surface that shields against interference frequencies in the radio frequency range may be provided. A structured metal surface (e.g., with slots) allows the shield to be made permeable to the gradients. In addition, discrete capacitors may be inserted in order to interconnect parts of the metal structure. By combining the approaches, a high degree of flexibility in terms of the design of the structure that is to be shielded and the frequencies that are to be shielded is provided.

The shielding for the electronic circuit is maximally high in the MR frequency range and maximally transparent to the gradient frequencies.

In one embodiment, the electronic circuit is arranged in a magnetic resonance tomography (MRT) system.

The subsections are capacitively connected by the substrate. This may be achieved through choice of a suitable substrate that may have at least a predefined loss, a predefined dielectric and a predefined substrate thickness. The loss, dielectric and substrate thickness influence the properties of the substrate and the capacitive coupling and may be adjusted according to specific parameters or scenarios.

In another embodiment, the substrate may include at least one of the following materials: an RF-suitable substrate (e.g., having a dielectric constant that is largely homogeneous across the desired frequency range) a ceramic (e.g., aluminum oxide), a polymer (e.g., Teflon), a glass fiber structure (e.g., FR4), and a dielectric (non-conductive) material.

For example, in one embodiment, the (conductive) metal structure includes non-magnetic material.

In another embodiment, the metal structure includes gold, silver, copper or aluminum.

In one embodiment, the metal structure is arranged on one side of the substrate. The subsections of the metal structure are connected to one another via components (e.g., capacitors and/or capacitance diodes).

Optionally, the concentrated components may also connect subsections of the metal structure that are arranged on both sides of the substrate.

For example, only parts of the individual separate subsections (e.g., not all subsections) may be connected to one another via capacitors.

Accordingly, the metal structure may be arranged on both sides of the substrate, and the subsections may be interconnected by capacitors. The capacitors are discrete components that may be mounted (e.g., permanently soldered) on the shield.

In one embodiment, the metal structure is arranged on both sides of the substrate such that the subsections arranged on both sides of the substrate partially overlap, thereby producing a capacitive coupling by the substrate in an area of the overlap.

The overlaps of the subsections result in a capacitance that forms a short circuit for the high frequencies that are to be shielded. For the low frequencies, the capacitance is an open circuit. The shield is therefore transparent to the low frequencies, and no significant eddy currents may be induced on the shield. If the capacitance is inadequate, a discrete component (e.g., a capacitor) may also be provided.

In one embodiment, the metal structure is connected to a ground of the electronic circuit that is to be shielded.

In another embodiment, the shield is arranged such that the shield at least partially shields the electronic circuit.

In one embodiment, an electronic circuit for a magnetic resonance tomography (MRT) system that has one embodiment of a shield is provided.

In another embodiment, an MRT system having an embodiment of at least one electronic circuit is provided.

### BRIEF DESCRIPTION OF THE DRAWINGS

For clarity of illustration reasons, like or like-acting elements may be provided with the same reference signs throughout.

FIG. 1 shows an exemplary layout of a structure shielding a source of interference; and

FIG. 2 shows another exemplary layout of a structure shielding a source of interference.

### DETAILED DESCRIPTION OF THE DRAWINGS

A double-sided structured surface made of a non-magnetic metal (e.g., copper) is applied onto a radio frequency (RF) substrate. The metal may be embodied with slots such that partial overlaps are produced between a top metal layer and a bottom metal layer mounted on the RF substrate.

The overlaps of the metal layers result in a capacitance that forms a short circuit for the high frequencies that are to be shielded. For the low frequencies, the capacitance constitutes an open circuit such that the metallization is transparent to the low frequencies, and no eddy currents may be induced.

This results in a frequency-selective surface. The metal may be connected to the ground of the electronic circuit that the metal shields.

The same effect may be achieved with the aid of discrete components and, for example, a substrate surface that is metallized and structured on one side.

The embodiments increase the degree of flexibility in the application of the structure, since additional degrees of freedom are created with respect to the thickness of the metallization, the substrate and the slot width.

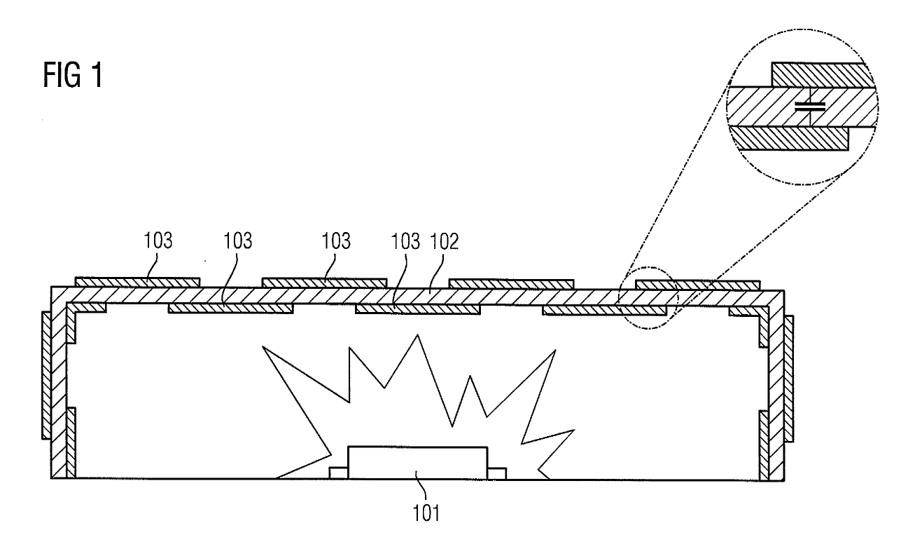

FIG. 1 shows an exemplary layout of a structure shielding a source of interference 101 (e.g., in the form of an electronic assembly). The structure includes an RF substrate 102, on both sides of which, partially overlapping, a non-magnetic (or weakly magnetic) metal structure 103 (e.g., made of copper) is applied. The metal structure 103 may have a plurality of individual parts that are fixedly mounted on the substrate 102, and the metal structure 103 may also be implemented as at least partially contiguous and/or perforated or slotted.

With the aid of the RF substrate 102 structured on both sides, capacitances are produced as a result of overlaps of the metal structure 103 applied on both sides of the substrate 102, according to the relation

$$C = {ɛ}_{r} \frac{A}{d} ,$$

where εᵣ denotes the relative permittivity (e.g., dielectric constant), A denotes the surface area of the electrode, and d denotes the distance between the electrodes.

The capacitance constitutes a short circuit for high frequencies and an open circuit for low frequencies. This results in the frequency-selective surface.

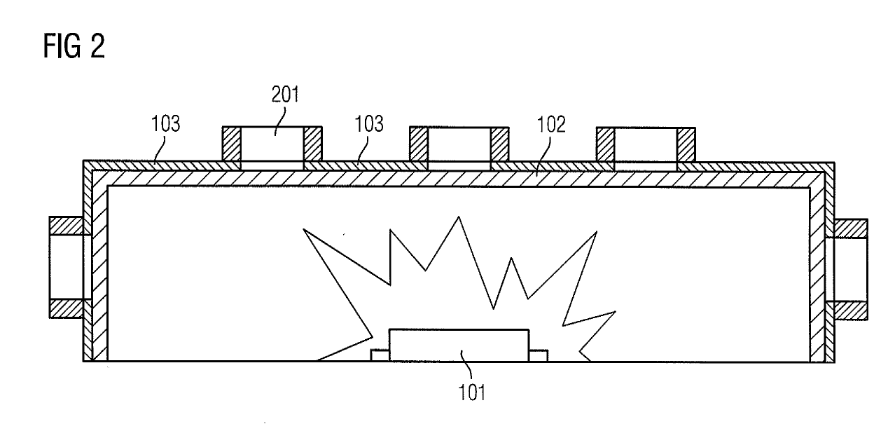

FIG. 2 shows an alternative embodiment to FIG. 1. The source of interference 101 is again hidden by the RF substrate 102. However, the metal structure 103 is only provided on one side of the substrate 102, with non-contiguous parts of the metal structure 103 being connected to one another via capacitors 201.

A frequency-selective surface that shields against interference frequencies in the radio frequency range may be achieved by the structuring of the substrate. Discrete capacitors may be employed for conductively connecting the individual elements of the structure at high frequencies. By combining the approaches, a high degree of flexibility is provided in terms of the design of the structure that is to be shielded and the frequencies that are to be shielded.

Although the invention has been illustrated and described in detail on the basis of the exemplary embodiments shown, the invention is not limited thereto, and other variations may be derived herefrom by the person skilled in the art without departing from the scope of protection of the invention.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A shield for an electronic circuit, the shield comprising:
a substrate; and
a metal structure that is arranged on at least one side of the substrate,
wherein the metal structure includes non-contiguous subsections, and
wherein the non-contiguous subsections of the metal structure are at least partially capacitively connected to one another.

2. The shield as claimed in claim 1, wherein the electronic circuit is arranged in a magnetic resonance tomography (MRT) system.

3. The shield as claimed in claim 1, wherein the substrate includes a radio-frequency-suitable substrate, a ceramic, a polymer, a glass fiber structure, a dielectric non-conductive material, or a combination thereof.

4. The shield as claimed in claim 1, wherein the metal structure comprises non-magnetic material.

5. The shield as claimed in claim 1, wherein the metal structure comprises gold, silver, copper or aluminum.

6. The shield as claimed in claim 1, wherein the metal structure is arranged on one side of the substrate, and
wherein the non-contiguous subsections of the metal structure are connected to one another via components.

7. The shield as claimed in claim 6, wherein the components comprise capacitors, capacitance diodes, or the capacitors and the capacitance diodes.

8. The shield as claimed in claim 1, wherein the metal structure is arranged on both sides of the substrate, and
wherein the non-contiguous subsections of the metal structure are connected to one another by way of components.

9. The shield as claimed in claim 8, wherein the components comprise capacitors, capacitance diodes, or the capacitors and the capacitance diodes.

10. The shield as claimed in claim 1, wherein the metal structure is arranged on both sides of the substrate such that the non-contiguous subsections arranged on both sides of the substrate partially overlap, thereby resulting in a capacitive coupling by the substrate in an area of the overlap.

11. The shield as claimed in claim 1, wherein the metal structure is connected to a ground of the electronic circuit that is to be shielded.

12. The shield as claimed in claim 1, wherein the shield is arranged such that the shield at least partially hides or shields the electronic circuit.

13. An electronic circuit for a magnetic resonance tomography (MRT) system, the electronic circuit comprising:
a shield comprising:
a substrate; and
a metal structure that is arranged on at least one side of the substrate,
wherein the metal structure includes non-contiguous subsections, and
wherein the non-contiguous subsections of the metal structure are at least partially capacitively connected to one another.

14. The electronic circuit as claimed in claim 13, wherein the electronic circuit is arranged in the magnetic resonance tomography (MRT) system.

15. The electronic circuit as claimed in claim 13, wherein the substrate includes a radio-frequency-suitable substrate, a ceramic, a polymer, a glass fiber structure, a dielectric non-conductive material, or a combination thereof.

16. The electronic circuit as claimed in claim 13, wherein the metal structure comprises non-magnetic material.

17. The electronic circuit as claimed in claim 13, wherein the metal structure comprises gold, silver, copper or aluminum.

18. The electronic circuit as claimed in claim 13, wherein the metal structure is arranged on one side of the substrate, and
wherein the non-contiguous subsections of the metal structure are connected to one another via components.

19. The electronic circuit as claimed in claim 18, wherein the components comprise capacitors, capacitance diodes, or the capacitors and the capacitance diodes.

20. A magnetic resonance tomography (MRT) system comprising:
at least one electronic circuit comprising:
a shield comprising:
a substrate; and
a metal structure that is arranged on at least one side of the substrate,
wherein the metal structure includes non-contiguous subsections, and
wherein the non-contiguous subsections of the metal structure are at least partially capacitively connected to one another.
